(19) United States
(12) Patent Application Publication
(10) Pub. No.: US 2024/0313092 A1
(43) Pub. Date: Sep. 19, 2024

(54) SEMICONDUCTOR DEVICE AND POWER AMPLIFIER INCLUDING THE SAME

(71) Applicant: SAMSUNG ELECTRO-MECHANICS CO., LTD., Suwon-si (KR)

(72) Inventors: Donghyeon LEE, Suwon-si (KR); Kyungmoon JUNG, Suwon-si (KR)

(73) Assignee: SAMSUNG ELECTRO-MECHANICS CO., LTD., Suwon-si (KR)

(21) Appl. No.: 18/410,355

(22) Filed: Jan. 11, 2024

(30) Foreign Application Priority Data
Mar. 15, 2023 (KR) 10-2023-0034092

(51) Int. Cl. H01L 29/73; H01L 27/082; H01L 29/08; H03F 3/213

(52) U.S. Cl. CPC H01L 29/7302; H01L 27/082; H01L 29/0804; H01L 29/0821; H03F 3/213

(57) ABSTRACT

A semiconductor device including a plurality of unit transistors, each of which is disposed on a semiconductor substrate and includes a collector electrode configured to output an output signal, a base electrode configured to receive an input signal, and an emitter electrode; and an emitter junction wiring interconnecting emitter electrodes of the plurality of unit transistors. In a thickness direction of the semiconductor substrate, a portion of the emitter junction wiring positioned between at least two unit transistors adjacent to each other among the plurality of unit transistors and another portion of the emitter junction wiring positioned outside of the two unit transistors have different thicknesses.

### CROSS-REFERENCE TO RELATED APPLICATIONS

This application claims the benefit under 35 USC § 119(a) of Korean Patent Application No. 10-2023-0034092, filed on Mar. 15, 2023, in the Korean Intellectual Property Office, the entire disclosure of which is incorporated herein by reference for all purposes.

### BACKGROUND

### 1. Field

The present disclosure relates to a semiconductor device and a power amplifier, including the same.

### 2. Description of the Background

Recently, with the increase in mobile devices, data communication has been advanced, and RF modules such as cellular front-end modules (FEMs) are growing. In addition, as the machine-to-machine (M2M) communication module market is being activated with the rise of the Internet of Things, products and services using various identification technologies are expected to increase. In this trend, the market and technological foundation of 5G high-speed communication, a new communication paradigm of communication, is being created, and it is expected that another inflection point will come.

5G communication has three advantages: “ultra-high speed and large capacity,” “ultra-low latency,” and “mass connection.” However, “mmWave,” which is greatly affected by obstacles, has a problem in that it is difficult to secure communication performance, and in order to improve the performance of wireless signals, robust design, as well as miniaturization, of parts are required. In this situation, power amplifier integrated circuit (PAIC) components, which determine the performance in 5G communication, have become more important, and it may be desired to improve communication performance while miniaturizing these components.

The transistor inside the PAIC serves to amplify the input voltage or current and send it to the output. However, if the junction between the transistor and the main circuit board is weak, current does not flow smoothly due to damage to the junction, and the quality of the transmission signal is greatly affected. Also, if the transistor is relatively small, it is relatively vulnerable to stress and possibly can crack. In addition, when the coefficient of thermal expansion (CTE) of the insulation material used is high, cracks may occur due to increased stress due to CTE mismatch at the heterogeneous interface.

The above information is presented as background information only to assist with an understanding of the present disclosure. No determination has been made, and no assertion is made, as to whether any of the above might be applicable as prior art with regard to the disclosure

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor device, includes a plurality of unit transistors, each of which is disposed on a semiconductor substrate and includes a collector electrode configured to output an output signal, a base electrode configured to receive an input signal, and an emitter electrode; and an emitter junction wiring interconnecting emitter electrodes of the plurality of unit transistors. In a thickness direction of the semiconductor substrate, a portion of the emitter junction wiring positioned between at least two unit transistors adjacent to each other among the plurality of unit transistors and another portion of the emitter junction wiring positioned outside of the two unit transistors have different thicknesses.

The emitter junction wiring may include a junction portion connected to the emitter electrode of one unit transistor of the plurality of unit transistors and a wiring portion extending to connect the emitter electrode of another unit transistor of the plurality of unit transistors. A first thickness of a portion of the wiring portion positioned outside the two unit transistors may be different from a second thickness of another portion of the wiring portion positioned between the two unit transistors.

The wiring portion may extend in a direction perpendicular to the thickness direction of the semiconductor substrate, and the junction portion may protrude from the wiring portion in the thickness direction of the semiconductor substrate.

The second thickness may be greater than the first thickness.

The semiconductor device may further include a collector wire connected to the collector electrode, and disposed between the collector electrode and the emitter junction wiring. In the thickness direction of the semiconductor substrate, a portion of the collector wire positioned outside of the two unit transistors and another portion of the collector wire positioned between the two unit transistors may have different thicknesses.

The collector wire may include a connection portion connected to the collector electrode, and a third thickness of the connection portion positioned outside of the two unit transistors may be different from a fourth thickness of the connection portion positioned between the two unit transistors.

The third thickness may be greater than the fourth thickness.

The semiconductor device may further include an insulation material covering the collector wire on the semiconductor substrate. The emitter junction wiring may be disposed to form an interface, and be in contact, with the insulation material.

Each of the plurality of unit transistors may be a bipolar transistor that includes a collector layer corresponding to the collector electrode, a base layer corresponding to the base electrode, and an emitter layer corresponding to the emitter electrode.

The semiconductor device may further include a metal pillar disposed to be in contact with the emitter junction wiring.

The emitter junction wiring may include gold (Au).

In another general aspect, a power amplifier for amplifying an RF input signal and outputting an RF output signal, the power amplifier includes a plurality of unit transistors, each of which is disposed on a semiconductor substrate and comprises a collector electrode configured to output the RF output signal, a base electrode configured to receive the RF input signal, and an emitter electrode; an emitter junction wiring interconnecting the emitter electrodes of the plurality of unit transistors; and a circuit board on which the plurality of unit transistors are mounted. In a thickness direction of the semiconductor substrate, a portion of the emitter junction wiring positioned between at least a two unit transistors adjacent to each other among the plurality of unit transistors and another portion of the emitter junction wiring positioned outside of the two unit transistors have different thicknesses.

The emitter junction wiring may include a junction portion connected to the emitter electrode of one unit transistor of the plurality of unit transistors and a wiring portion extending to connect the emitter electrode of another unit transistor of the plurality of unit transistors. A first thickness of a portion of the wiring portion positioned outside the two unit transistors may be different from a second thickness of another portion of the wiring portion positioned between the two unit transistors.

The power amplifier may further include a collector wire connected to the collector electrode, and disposed between the collector electrode and the emitter junction wiring. In the thickness direction of the semiconductor substrate, a portion of the collector wire positioned outside of the two unit transistors and another portion of the collector wire positioned between the two unit transistors may have different thicknesses.

The collector wire may include a connection portion connected to the collector electrode. A third thickness of the connection portion positioned outside of the two unit transistors may be different from a fourth thickness of the connection portion positioned between the two unit transistors.

Each of the plurality of unit transistors may be a bipolar transistor that includes a collector layer corresponding to the collector electrode, a base layer corresponding to the base electrode, and an emitter layer corresponding to the emitter electrode.

Other features and aspects will be apparent from the following detailed description, the drawings, and the claims

### BRIEF DESCRIPTION OF THE DRAWINGS

FIG. 1 is a layout image schematically showing a drive amplifier in a power amplifier according to an embodiment.

FIG. 2 is a top plan view showing a unit transistor in the drive amplifier, as shown in FIG. 1.

FIG. 3 is a cross-sectional view taken along line III-III′ of FIG. 2.

FIG. 4 is a cross-sectional view taken along line IV-IV′ of FIG. 1.

FIG. 5 is a cross-sectional view showing a drive amplifier according to a comparative example.

FIG. 6 is a simulation result obtained by only the emitter junction wiring portion extracted from the drive amplifier structure according to the comparative example shown in FIG. 5.

FIG. 7 is a simulation result obtained by only the emitter junction wiring portion extracted from the drive amplifier structure according to the embodiment shown in FIG. 4.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

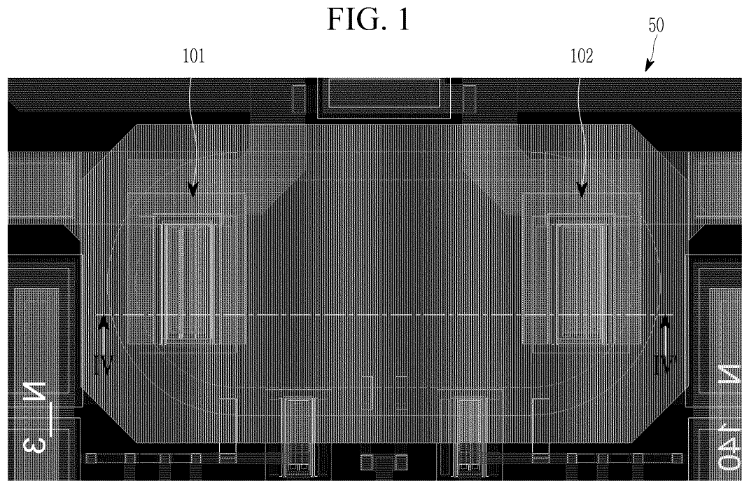

FIG. 1 is a layout image schematically showing a drive amplifier in a power amplifier according to an embodiment.

A power amplifier integrated circuit (PAIC) used as a power amplifier is an electronic device that integrates a power amplifier into a single chip. It may be used in wireless communication systems such as mobile phones and Wi-Fi routers to amplify signals and increase system range. PAICs are designed to deliver high-output power while maintaining good linearity and efficiency, and are available in a variety of power levels and frequency bands to suit a variety of applications.

Within the power amplifier, a drive amplifier 50 may provide desired input signals to a power amplifier core, and may be used to provide the desired gain and power to drive the power amplifier core. The drive amplifier first amplifies an RF input signal before being coupled to the power amplifier core.

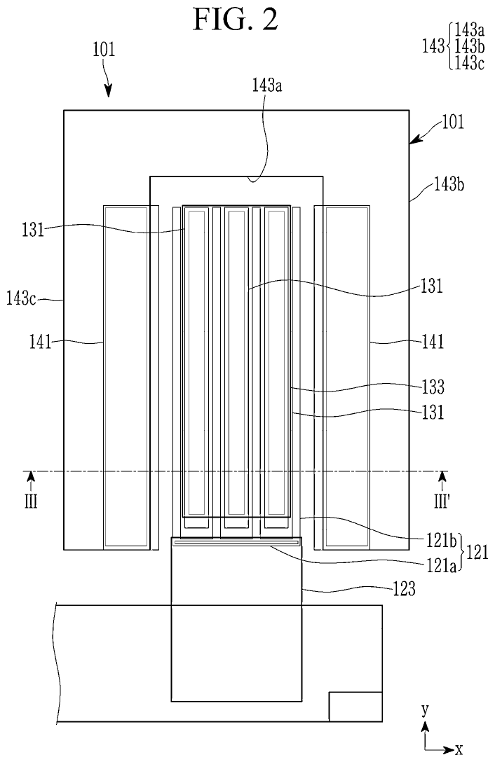

Referring to FIG. 1, the drive amplifier 50 includes two unit transistors 101 and 102 spaced apart from each other on a plane and electrically connected in parallel. That is, in each of the two unit transistors 101 and 102, a base electrode 121 (refer to FIG. 2) may be connected to a common input wire to receive a common RF input signal, and a collector electrode 141 (refer to FIG. 2) may be connected to a common output wire to output an amplified RF output signal. Also, in each of the two unit transistors 101 and 102, an emitter electrode 131 (refer to FIG. 2) may be connected to the ground.

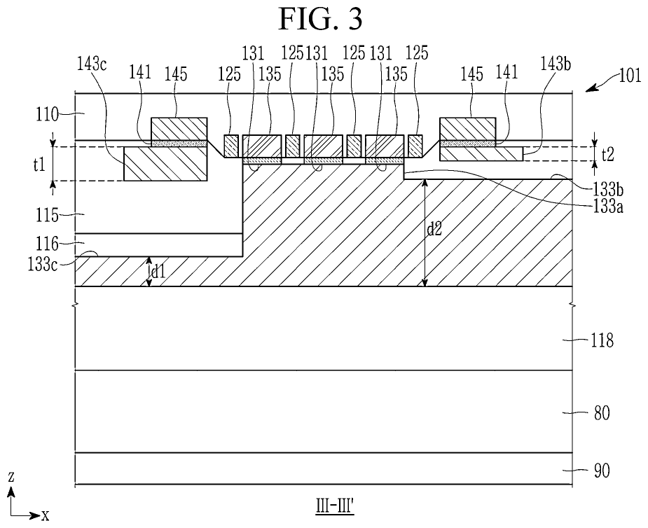

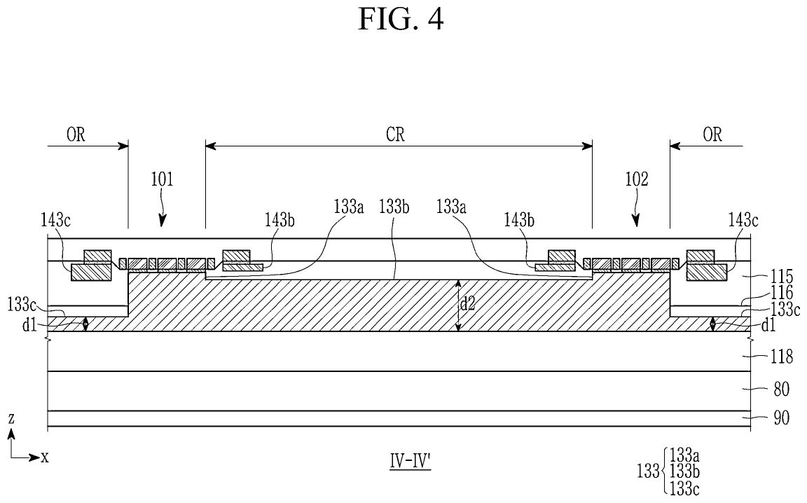

FIG. 2 is a top plan view showing a unit transistor in the drive amplifier, as shown in FIG. 1. FIG. 3 is a cross-sectional view taken along line III-III′ of FIG. 2. FIG. 4 is a cross-sectional view taken along line IV-IV′ of FIG. 1.

Referring to FIG. 2, a unit transistor 101, according to the present embodiment, may be a bipolar transistor, and includes the base electrode 121, the emitter electrode 131, and the collector electrode 141. The base electrode 121 may be connected to the input wire where the RF input signal is input, and the collector electrode 141 may be connected to the output wire where the RF output signal is output. The emitter electrode 131 may be connected to the ground through an emitter junction wiring 133.

The unit transistor 101 includes a semiconductor substrate 110 (refer to FIG. 3), and the base electrode 121, the emitter electrode 131, and the collector electrode 141 are disposed on the semiconductor substrate 110. An input RF signal is input to the base electrode 121, and an output RF signal is output from the collector electrode 141.

The base electrode 121 may be connected to a base wire 123, the emitter electrode 131 may be connected to the emitter junction wiring 133, and the collector electrode 141 may be connected to a collector wire 143. The base wire 123, the emitter junction wiring 133, and the collector wire 143 may be positioned in different layers, respectively, from the base electrode 121, the emitter electrode 131, and the collector electrode 141 along a thickness direction of the semiconductor substrate 110 (z-axis direction in the drawing, hereinafter, also referred to as the thickness direction of the substrate) (refer to FIG. 3).

The base electrode 121 includes a coupling portion 121a and a plurality of branch portions 121b that are positioned on the same plane. The plurality of branch portions 121b extend parallel to each other in a first direction (y-axis direction in the drawing) and may be connected to each other by the coupling portion 121a. The coupling portion 121a may extend in a second direction (x-axis direction in the drawing) that is perpendicular to the direction along which the plurality of branch portions 121b extend. The base wire 123 positioned in a layer different from a layer where the base electrode 121 is positioned has an overlapping portion in the thickness direction of the substrate at the coupling portion 121a of the base electrode 121, and may be connected to each other.

The emitter electrode 131 includes a plurality of elongated rectangular electrodes, each extending in the first direction. Each plurality of emitter electrode 131 may be disposed between the plurality of branch portions 121b of the base electrode 121 when viewed from a plan view. Long sides of the emitter electrode 131 are disposed adjacent to both sides of the branch portion 121b of the base electrode 121, one short side of the emitter electrode 131 is disposed adjacent to the coupling portion 121a of the base electrode 121, and a remaining short side of the emitter electrode 131 is opened. Accordingly, the emitter electrode 131 may be disposed to have three edges surrounded by the base electrode 121.

The collector electrode 141 may be disposed on both outer sides of the base electrode 121 when viewed from a plan view. The collector electrode 141 may be formed of a rectangular electrode extending in the first direction. The collector electrode 141 of the rectangular shape may extend along the first direction by a length of the base electrode 121. In the second direction, the width of each collector electrode 141 may be narrower than the entire width of the base electrode 121 and wider than the width of each emitter electrode 131.

The collector wire 143 positioned in a layer different from a layer where the collector electrode 141 is positioned has an overlapping portion with at least a part of the collector electrode 141 in the thickness direction of the substrate, and may be connected to each other. The collector wiring 143 at least partially overlaps the collector electrode 141. The collector wiring 143 includes connection portions 143b and 143c extending in the first direction and a common portion 143a extending in the second direction and connecting the connection portions 143b and 143c. Accordingly, when viewed from a plan view, the collector wire 143 may be disposed to surround three edges of the base electrode 121 and the emitter electrode 131, and the common portion 143a of the collector wire 143 may be disposed to face the coupling portion 121a of the base electrode 121.

FIG. 3 is an enlarged cross-sectional view of a unit transistor in a drive amplifier according to the present embodiment.

Referring to FIG. 3, the unit transistor 101, according to the present embodiment, may form a part of the semiconductor device as the base electrode 121 (refer to FIG. 2), the emitter electrode 131, and the collector electrode 141 are formed on the semiconductor substrate 110. FIG. 3 illustrates that the base electrode 121, the emitter electrode 131, and the collector electrode 141 formed on the semiconductor substrate 110 are positioned toward the printed circuit board 90, such that the semiconductor device may be mounted on a printed circuit board 90.

The emitter electrode 131 is interconnected with the emitter electrode 131 of another unit transistor 102 (refer to FIG. 4) through the emitter junction wiring 133, and a connection end of the semiconductor device may be configured by covering the emitter junction wiring 133 by a metal pillar 118. The semiconductor device may be mounted on the printed circuit board 90 as the metal pillar 118 is bonded to the printed circuit board 90 by a solder 80. At this time, the metal pillar 118 may be connected to a ground wire on the printed circuit board 90 while forming a ground layer. For example, the emitter junction wiring 133 may include gold (Au), and the metal pillar 118 may include copper (Cu).

In the unit transistor 101, a collector layer 145, a base layer 125, and an emitter layer 135 are stacked on the semiconductor substrate 110. The collector layer 145 may be an n-type, the base layer 125 may be a p-type, and the emitter layer 135 may be an n-type silicon layer.

The collector electrode 141 may be disposed on the collector layer 145, the base electrode 121 may be disposed on the base layer 125, and the emitter electrode 131 may be disposed on the emitter layer 135. With reference to a surface of the semiconductor substrate 110 in the thickness direction of the substrate, the base electrode 121 may be positioned higher than the collector electrode 141, and the emitter electrode 131 may be positioned higher than the base electrode 121. That is, with reference to the printed circuit board 90, the emitter electrode 131 may be positioned closer to the printed circuit board 90 than the base electrode 121, and the base electrode 121 may be positioned closer to the printed circuit board 90 than the collector electrode 141.

The collector wire 143 may be disposed on the collector electrode 141. The collector wire 143 may be formed to be thicker and wider than the collector electrode 141. Since the collector electrode 141 is respectively disposed at both sides, interposing the base electrode 121 and the emitter electrode 131, the collector wire 143 may include, corresponding thereto, the connection portions 143b and 143c respectively disposed at both sides, interposing the base electrode 121 and the emitter electrode 131.

The emitter junction wiring 133 may be disposed on the emitter electrode 131. The emitter junction wiring 133 includes a junction portion 133a connected to the emitter electrode 131 and wiring portions 133b and 133c extending to interconnect emitter electrodes of different unit transistors. The junction portion 133a may protrude from the wiring portions 133b and 133c in the thickness direction of the substrate and be connected to the emitter electrode 131. Accordingly, the emitter junction wiring 133 may avoid the collector wire 143 and be connected to the emitter electrode 131.

In the present embodiment, in connection with thicknesses of the wiring portions 133b and 133c of the emitter junction wiring 133 according to the thickness direction of the substrate, thicknesses of the wiring portions 133b and 133c positioned at both sides interposing the base electrode 121 and the emitter electrode 131 are different from each other. With reference to FIG. 3, a second thickness d2 of the wiring portion 133b, positioned to the right, is thicker than a first thickness d1 of the wiring portion 133c positioned to the left.

In the present embodiment, the connection portions 143b and 143c of the collector wire 143, respectively, disposed at both sides, interposing the base electrode 121 and the emitter electrode 131, may have different thicknesses in the thickness direction of the substrate. That is, a third thickness t1 of a connection portion 143c of the collector wire 143 facing the wiring portion 133c of the emitter junction wiring 133 may be thicker than a fourth thickness t2 of a connection portion 143b facing the wiring portion 133b.

Insulation materials 115 and 116 may be filled between the emitter junction wiring 133 and the collector wire 143. The insulation materials 115 and 116 may be filled on the semiconductor substrate 110 to cover the collector wire 143, the collector electrode 141, and the base electrode 121. The insulation materials 115 and 116 may include a first insulation material 115 containing silicon nitride (SiN), and a second insulation material 116 containing polybenzoxazole (PBO). The first insulation material 115 may be positioned on the semiconductor substrate 110 to cover the collector wire 143, and the second insulation material 116 may be positioned between the wiring portion 133b of the emitter junction wiring 133 and the first insulation material 115.

FIG. 4 is an enlarged cross-sectional view of a pair of unit transistors in a drive amplifier according to the present embodiment.

Referring to FIG. 4, a region between a pair of unit transistors 101 and 102 adjacent to each other may be a closed region CR, and both outer side regions of the pair of unit transistors 101 and 102 adjacent to each other may be relatively open regions OR.

In connection with thicknesses in the thickness direction of the substrate (z-axis direction in the drawing), the second thickness d2 of the wiring portion 133b of the emitter junction wiring 133 disposed in the closed region CR may be formed thicker than the first thickness d1 of the wiring portion 133c of the emitter junction wiring 133 positioned in the open region OR. Specifically, the second thickness d2 of the wiring portion 133b of the emitter junction wiring 133 connecting the emitter electrodes 131 of the pair of unit transistors 101 and 102 adjacent to each other may be formed thicker than the first thickness d1 of the wiring portion 133c of the emitter junction wiring 133 positioned outside the emitter electrodes 131 of the pair of unit transistors 101 and 102. Accordingly, the emitter junction wiring 133 connecting the emitter electrodes 131 of the pair of unit transistors 101 and 102 may be integrated.

The fourth thickness t2 of the connection portion 143b of the collector wire 143 positioned in the closed region CR (refer to FIG. 3) may be formed thinner than the third thickness t1 of the connection portion 143c of the collector wire 143 positioned in the open region OR (refer to FIG. 3). Accordingly, even if the thickness of the wiring portion 133b of the emitter junction wiring 133 interconnecting the emitter electrodes 131 of the pair of unit transistors 101 and 102 becomes thicker, since the thickness of the connection portion 143b of the collector wire 143 facing thereto is thin, they may be disposed without interference.

The insulation materials 115 and 116 may be filled between the emitter junction wiring 133 and the collector wire 143, the closed region CR may be filled with the first insulation material 115 only, and the open region OR may be filled with the first insulation material 115 and the second insulation material 116 in the stacked manner. Accordingly, the second insulation material 116, containing polybenzoxazole (PBO) with a high coefficient of thermal expansion, may be omitted from the closed region CR.

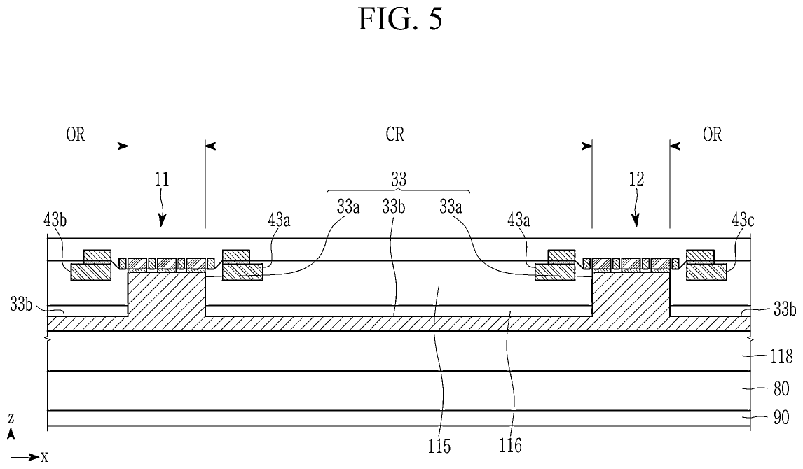

FIG. 5 is a cross-sectional view showing a drive amplifier according to a comparative example.

Referring to FIG. 5, in connection with thicknesses in the thickness direction of the substrate (z-axis direction in the drawing), a thickness of a wiring portion 33b of an emitter junction wiring 33 disposed between a pair of unit transistors 11 and 12 adjacent to each other is the same as a thickness of a wiring portion 33c of the emitter junction wiring 33 positioned in both outer sides of the pair of unit transistors 11 and 12. That is, wiring portions 33b and 33c disposed in the closed region CR and the open region OR have the same thickness. Accordingly, only junction portions 33a of the emitter junction wiring 33 protrudes to be connected to the emitter electrode, and the wiring portions 33b and 33c of the emitter junction wiring 33 may have a uniform thickness.

According to a comparative example, the first insulation material 115 and the second insulation material 116 may be stacked between junction portions 33a of the emitter junction wirings 33 of the pair of unit transistors 11 and 12. The first insulation material 115 may include silicon nitride (SiN), and the second insulation material 116 may include polybenzoxazole (PBO).

The second insulation material 116, containing polybenzoxazole (PBO), has a coefficient of thermal expansion (CTE) higher than the first insulation material 115, containing silicon nitride (SiN). The second insulation material 116 also has a coefficient of thermal expansion (CTE) higher than an adjacent emitter junction wiring 33 containing gold (Au). For example, the coefficient of thermal expansion of silicon nitride (SiN) may be 2.8 ppm/° C., a modulus of elasticity thereof may be 270 GPa, the coefficient of thermal expansion of polybenzoxazole (PBO) may be 97 ppm/° C., a modulus of elasticity thereof may be 2.2 GPa, the coefficient of thermal expansion of gold (Au) may be 14 ppm/° C., and a modulus of elasticity thereof may be 79 GPa.

When a signal is transmitted, the temperature rises due to transistor power amplification, resulting in the second insulation material 116 containing polybenzoxazole (PBO) greatly expanding compared to the first insulation material 115 or the emitter junction wiring 33 in the vicinity. In this case, since the closed region CR has relatively greater stress due to the expansion of the polybenzoxazole (PBO) than the open region OR, the maximum stress may act on the lower part of the transistor in the closed region CR. Such stress concentration may cause cracks at the heterogeneous interface.

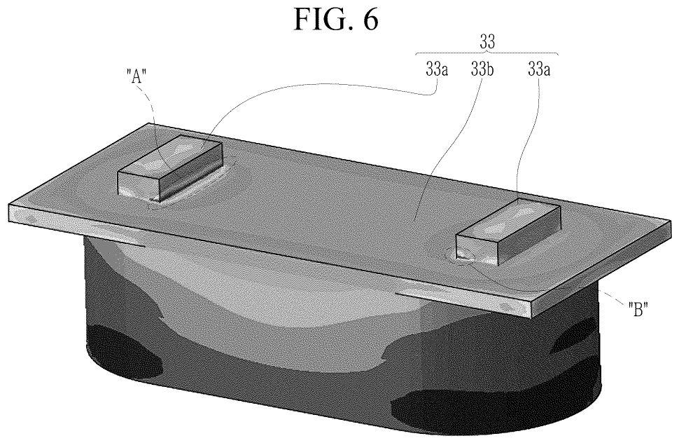

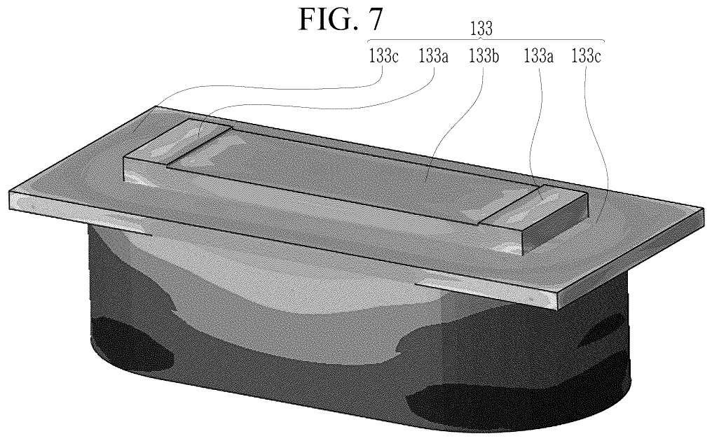

FIG. 6 is a simulation result obtained by only the emitter junction wiring portion extracted from the drive amplifier structure according to the comparative example shown in FIG. 5. FIG. 7 is a simulation result obtained by only the emitter junction wiring portion extracted from the drive amplifier structure according to the embodiment shown in FIG. 4.

Referring to FIG. 6, a high stress concentration occurs in a portion where the emitter junction wiring 43 of the drive amplifier structure, according to the comparative example, is adjacent to the second insulation material 116 containing polybenzoxazole (PBO) (parts “A” and “B” of the drawing). This is believed to be due to the expansion of polybenzoxazole (PBO), which has a higher thermal expansion coefficient than gold (Au).

Referring to FIG. 7, in the emitter junction wiring 133 of the drive amplifier structure according to an embodiment, as a result of forming the wiring portion 133b of the closed region CR to be thicker than the wiring portion 133c of the open region OR, in comparison with the comparative example, normalized stress is expected to decrease by 34% level (base on temperature rise from 25° C. to 155° C. when the transistor is operating). That is, while the maximum stress normalized value is 1.00 in the comparative example, the maximum stress normalized value is expected to be 0.66 in an embodiment.

Therefore, by integrating junction portions of the emitter junction wiring 133 between the pair of unit transistors 101 and 102, stress caused by a mismatch in coefficients of thermal expansion at the heterogeneous interface of the closed region CR may be removed. As the stress at the heterogeneous interface is reduced in this way, the effect of reducing crack defects in the junction may be expected, thus improving fatigue life due to the increased design robustness of the junction.

According to a semiconductor device and a power amplifier including the same according to an embodiment, stress of the transistor inside the power amplifier may be reduced in structural aspect, and the possibility of cracks may be decreased.

By integrating the junction portions of the emitter junction wiring between two unit transistors, stress caused by a mismatch in coefficients of thermal expansion at the heterogeneous interface of the closed region CR may be decreased. As the stress at the heterogeneous interface is reduced in this way, the effect of reducing crack defects in the junction may be expected, and furthermore, the fatigue life may be improved due to the effect of increasing the design robustness of the junction.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A semiconductor device, comprising:
a plurality of unit transistors, each of which is disposed on a semiconductor substrate and comprises a collector electrode configured to output an output signal, a base electrode configured to receive an input signal, and an emitter electrode; and
an emitter junction wiring interconnecting emitter electrodes of the plurality of unit transistors,
wherein, in a thickness direction of the semiconductor substrate, a portion of the emitter junction wiring positioned between at least two unit transistors adjacent to each other among the plurality of unit transistors and another portion of the emitter junction wiring positioned outside of the two unit transistors have different thicknesses.

2. The semiconductor device of claim 1, wherein:
the emitter junction wiring comprises a junction portion connected to the emitter electrode of one unit transistor of the plurality of unit transistors and a wiring portion extending to connect the emitter electrode of another unit transistor of the plurality of unit transistors; and
a first thickness of a portion of the wiring portion positioned outside the two unit transistors is different from a second thickness of another portion of the wiring portion positioned between the two unit transistors.

3. The semiconductor device of claim 2, wherein the wiring portion extends in a direction perpendicular to the thickness direction of the semiconductor substrate, and the junction portion protrudes from the wiring portion in the thickness direction of the semiconductor substrate.

4. The semiconductor device of claim 2, wherein the second thickness is greater than the first thickness.

5. The semiconductor device of claim 1, further comprising a collector wire connected to the collector electrode, and disposed between the collector electrode and the emitter junction wiring,
wherein, in the thickness direction of the semiconductor substrate, a portion of the collector wire positioned outside of the two unit transistors and another portion of the collector wire positioned between the two unit transistors have different thicknesses.

6. The semiconductor device of claim 5, wherein:
the collector wire comprises a connection portion connected to the collector electrode; and
a third thickness of the connection portion positioned outside of the two unit transistors is different from a fourth thickness of the connection portion positioned between the two unit transistors.

7. The semiconductor device of claim 6, wherein the third thickness is greater than the fourth thickness.

8. The semiconductor device of claim 5, further comprising an insulation material covering the collector wire on the semiconductor substrate,
wherein the emitter junction wiring is disposed to form an interface, and be in contact, with the insulation material.

9. The semiconductor device of claim 1, wherein each of the plurality of unit transistors is a bipolar transistor that comprises a collector layer corresponding to the collector electrode, a base layer corresponding to the base electrode, and an emitter layer corresponding to the emitter electrode.

10. The semiconductor device of claim 1, further comprising a metal pillar disposed to be in contact with the emitter junction wiring.

11. The semiconductor device of claim 1, wherein the emitter junction wiring comprises gold (Au).

12. A power amplifier for amplifying an RF input signal and outputting an RF output signal, the power amplifier comprising:
a plurality of unit transistors, each of which is disposed on a semiconductor substrate and comprises a collector electrode configured to output the RF output signal, a base electrode configured to receive the RF input signal, and an emitter electrode;
an emitter junction wiring interconnecting the emitter electrodes of the plurality of unit transistors; and
a circuit board on which the plurality of unit transistors are mounted,
wherein, in a thickness direction of the semiconductor substrate, a portion of the emitter junction wiring positioned between at least a two unit transistors adjacent to each other among the plurality of unit transistors and another portion of the emitter junction wiring positioned outside of the two unit transistors have different thicknesses.

13. The power amplifier of claim 12, wherein:
the emitter junction wiring comprises a junction portion connected to the emitter electrode of one unit transistor of the plurality of unit transistors and a wiring portion extending to connect the emitter electrode of another unit transistor of the plurality of unit transistors; and
a first thickness of a portion of the wiring portion positioned outside the two unit transistors is different from a second thickness of another portion of the wiring portion positioned between the two unit transistors.

14. The power amplifier of claim 12, further comprising a collector wire connected to the collector electrode, and disposed between the collector electrode and the emitter junction wiring,
wherein, in the thickness direction of the semiconductor substrate, a portion of the collector wire positioned outside of the two unit transistors and another portion of the collector wire positioned between the two unit transistors have different thicknesses.

15. The power amplifier of claim 14, wherein:
the collector wire comprises a connection portion connected to the collector electrode; and
a third thickness of the connection portion positioned outside of the two unit transistors is different from a fourth thickness of the connection portion positioned between the two unit transistors.

16. The power amplifier of claim 12, wherein each of the plurality of unit transistors is a bipolar transistor that comprises a collector layer corresponding to the collector electrode, a base layer corresponding to the base electrode, and an emitter layer corresponding to the emitter electrode.
